(19) United States
(12) Patent Application Publication
(10) Pub. No.: US 2019/0331507 A1
(43) Pub. Date: Oct. 31, 2019

(54) MULTI-TURN SENSOR

(71) Applicant: BOURNS, INC., Riverside, CA (US)

(72) Inventors: Eugen BOGOS, Lake Elsinore, CA (US); Perry WEHLMANN, Corona, CA (US); Cameron SCHAEFER, Riverside, CA (US); Brandon COUNCIL, Riverside, CA (US)

(21) Appl. No.: 16/394,973

(22) Filed: Apr. 25, 2019

Related U.S. Application Data
(60) Provisional application No. 62/663,231, filed on Apr. 26, 2018.

(51) Int. Cl. G01D 5/14; G01D 5/04; G01B 7/30; G01R 33/09

(52) U.S. Cl. CPC G01D 5/145; G01R 33/09; G01B 7/30; G01D 5/04

(57) ABSTRACT

A multi-turn sensor can include first and second shafts having respective rotational axes that are approximately perpendicular to each other, a first magnet provided at an end of the first shaft, and a second magnet provided at an end of the second shaft. The multi-turn sensor can further include a first magnetic sensor provided adjacent the first magnet to allow non-contacting sensing of angular position of the first shaft as the first shaft rotates, and a second magnetic sensor provided adjacent the second magnet to allow non-contacting sensing of angular position of the second shaft as the second shaft rotates. The multi-turn sensor can further include a gear mechanism configured to couple the first shaft and the second shaft, such that the rotation of the first shaft results in the rotation of the second shaft.

### CROSS-REFERENCE TO RELATED APPLICATION(S)

This application claims priority to U.S. Provisional Application No. 62/663,231 filed Apr. 26, 2018, entitled MULTI-TURN SENSOR, the disclosure of which is hereby expressly incorporated by reference herein in its respective entirety.

### BACKGROUND

### Field

The present disclosure generally relates to multi-turn sensors.

### Description of the Related Art

In many mechanical and/or electromechanical devices, it is desirable to accurately determine rotational position of an object such as a shaft. In such applications, it is also desirable to measure such a rotational position over a plurality of turns of the object.

### SUMMARY

In some implementations, the present disclosure relates to a multi-turn sensing device that includes a first shaft having a first rotational axis, and a second shaft having a second rotational axis that is approximately perpendicular to the first rotational axis. The multi-turn sensing device further includes a first magnet provided at an end of the first shaft, and a second magnet provided at an end of the second shaft. The multi-turn sensing device further includes a first magnetic sensor provided adjacent the first magnet along the first rotational axis to allow non-contacting sensing of angular position of the first shaft as the first shaft rotates about the first rotational axis, and a second magnetic sensor provided adjacent the second magnet along the second rotational axis to allow non-contacting sensing of angular position of the second shaft as the second shaft rotates about the second rotational axis. The multi-turn sensing device further includes a gear mechanism configured to couple the first shaft and the second shaft, such that the rotation of the first shaft results in the rotation of the second shaft.

In some embodiments, the gear mechanism can be configured such that one turn of the first shaft results in one turn of the second shaft. Such one turn of the first shaft can result in one turn of the first magnet relative to the first magnetic sensor, and the one turn of the second shaft can result in one turn of the second magnet relative to the second magnetic sensor.

In some embodiments, the gear mechanism can be configured such that one turn of the first shaft results in less than or more than one turn of the second shaft.

In some embodiments, each of the first magnet and the second magnet can include a bipolar and diametrally magnetized magnet configured to provide variable orthogonal and parallel magnetic fluxes to the respective magnetic sensor. In some embodiments, each of the first magnetic sensor and the second magnetic sensor can be configured to operate in quadrature mode, and include a plurality of Hall-effect sensors, a plurality of magneto-resistive (MR) sensors, or a plurality of giant magnetic resistive (GMR) sensors. In some embodiments, each of the first magnetic sensor and the second magnetic sensor can include four sensors positioned in quadrature and configured to operate as sine-cosine sensors.

In some embodiments, the multi-turn sensing device can further include an interface configured to process output signals from each of the first magnetic sensor and the second magnetic sensor and provide one or more output signals.

In some embodiments, each magnetic sensor or the interface can be configured to generate a digital signal representative of the angular position of the respective magnet, and the interface can be configured to convert the digital signal into a corresponding analog signal as the output signal.

In some embodiments, the interface can be configured to generate a common output signal representative of a combination of the output signals of the first and second magnetic sensors. The output signal of the first magnetic sensor can be representative of the angular position of the first shaft in a current turn, and the output signal of the second magnetic sensor can be representative of a turn number of the first shaft, such that the common output signal includes information about the turn number of the first shaft and the angular position of the first shaft in the current turn.

In some embodiments, the interface can be configured to generate a device output signal representative of each of the output signals of the first and second magnetic sensors.

In some embodiments, at least the first magnetic sensor and the interface can be parts of, or disposed on, an application specific integrated circuit (ASIC). In some embodiments, the multi-turn sensing device can further include a shielding layer configured to shield some or all of the ASIC from radiation.

In some embodiments, the multi-turn sensing device can further include a housing configured to house the first and second magnetic sensors, the first and second magnets, the second shaft, and at least a portion of the first shaft.

In some embodiments, the first shaft can be configured to be coupled to an external part, such that the device is able to measure an angular position of the external part in a current turn with the first magnetic sensor, and a turn number of the external part with the second magnetic sensor, such that the device is able to provide information about the turn number of the external part and the angular position of the external part in the current turn.

In some embodiments, the gear mechanism can include a threaded portion of the first shaft and a gear wheel configured to engage the threaded portion and turn with the second shaft.

In some implementations, the present disclosure relates to a method for sensing rotational position. The method includes sensing an angular position of a first shaft within a given turn of the first shaft about a first rotational axis. The sensing of the angular position includes sensing of an angular position of a first magnet provided at an end of the first shaft with a first magnetic sensor provided adjacent the first magnet along the first rotational axis to allow non-contacting sensing of the angular position of the first shaft. The method further includes determining a turn number of the first shaft with a second shaft that is coupled to the first shaft through a gear mechanism having a second rotational axis that is approximately perpendicular to the first rotational axis. The determining of the turn number includes sensing of an angular position of a second magnet provided at an end of the second shaft with a second magnetic sensor provided adjacent the second magnet along the second rotational axis to allow non-contacting sensing of the angular position of the second shaft as the second shaft rotates due to the rotation of the first shaft.

In some implementations, the present disclosure relates to a system that includes a first device for which determination of its position is desired, and a multi-turn sensor coupled to the first device and configured to provide an output signal representative of the position of the first device. The multi-turn sensor includes a first shaft having a first rotational axis and configured to provide the coupling with the first device, and a second shaft having a second rotational axis that is approximately perpendicular to the first rotational axis. The multi-turn sensor further includes a first magnet provided at an end of the first shaft, and a second magnet provided at an end of the second shaft. The multi-turn sensor further includes a first magnetic sensor provided adjacent the first magnet along the first rotational axis to allow non-contacting sensing of angular position of the first shaft as the first shaft rotates about the first rotational axis, and a second magnetic sensor provided adjacent the second magnet along the second rotational axis to allow non-contacting sensing of angular position of the second shaft as the second shaft rotates about the second rotational axis. The multi-turn sensor further includes a gear mechanism configured to couple the first shaft and the second shaft, such that the rotation of the first shaft results in the rotation of the second shaft.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows a front perspective view of a multi-turn sensor.

FIG. 2 shows a back perspective view of the multi-turn sensor of FIG. 1.

FIG. 3 shows an exploded view of the multi-turn sensor of FIG. 1 in a back perspective view.

FIG. 4 shows an exploded view of the multi-turn sensor of FIG. 1 in a front perspective view.

FIG. 5 shows a back perspective view of the multi-turn sensor of FIG. 1, but with some parts removed to better show internal workings.

FIG. 6 shows a side view of the assembly of FIG. 5.

FIG. 7 shows a bottom view of the assembly of FIG. 5.

FIG. 8 depicts a block diagram of an example of how the multi-turn sensor of FIG. 1 can be operated.

FIG. 9 shows an example multi-turn sensor having separate input/output terminals for first and second sensors.

FIG. 10 shows the multi-turn sensor of FIG. 9, but with some parts removed to better show internal features.

FIG. 11 depicts a block diagram of an example of how the multi-turn sensor of FIG. 10 can be operated.

### DETAILED DESCRIPTION OF SOME EMBODIMENTS

The headings provided herein, if any, are for convenience only and do not necessarily affect the scope or meaning of the claimed invention.

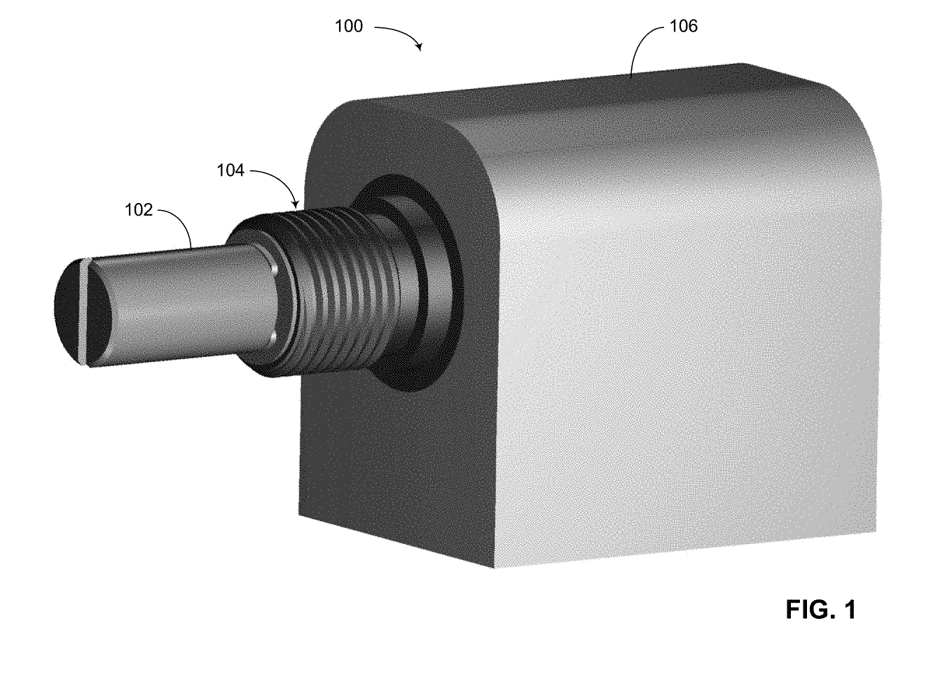

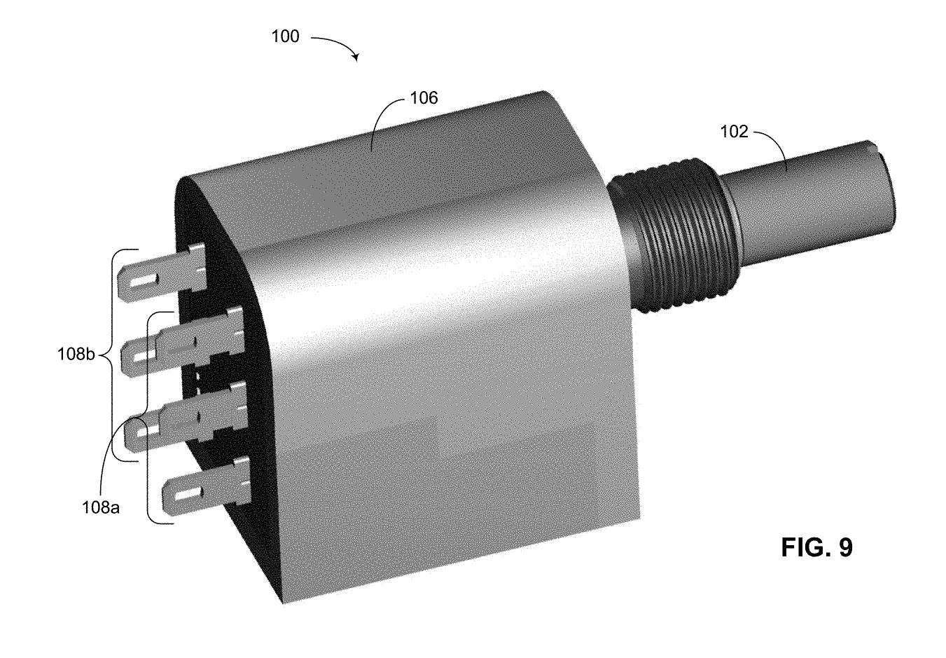

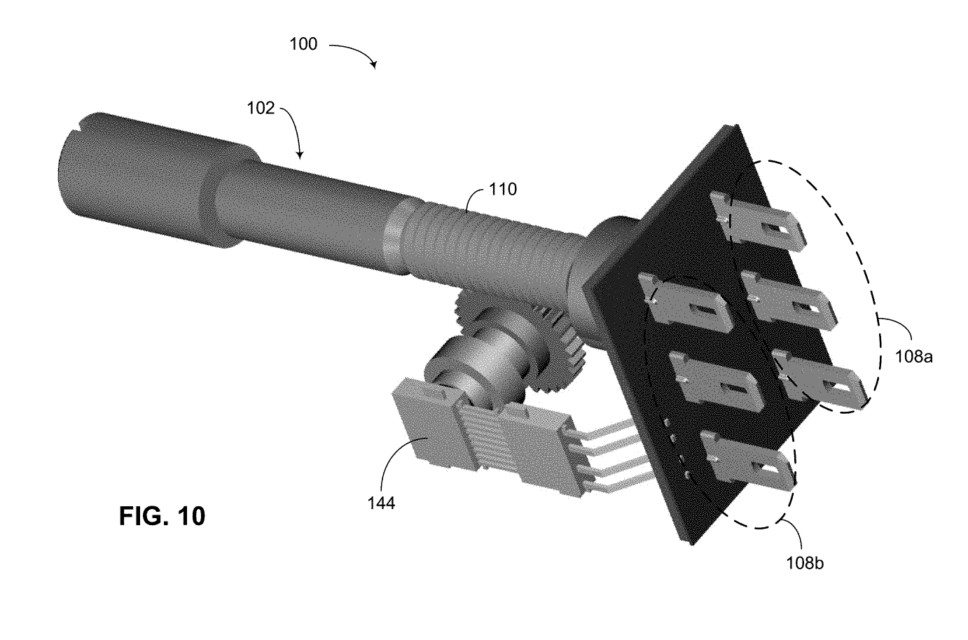

FIGS. 1-11 show various views and/or variations of a multi-turn sensor 100 having one or more features as described herein. More particularly, FIGS. 1-8 show various views of an example embodiment in which a common set of input/output (I/O) terminals can be provided for a multi-turn sensor, and FIGS. 9-11 show various views of an another example embodiment in which more than one set of I/O terminals can be provided for a multi-turn sensor.

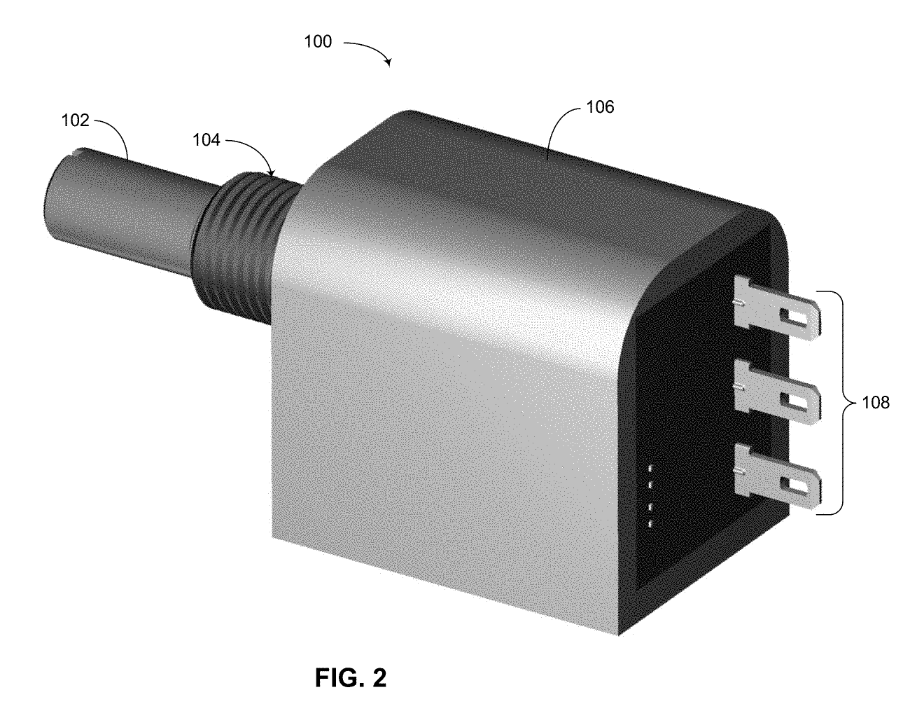

Referring to FIGS. 1-8, FIG. 1 shows a front perspective view of a multi-turn sensor 100, and FIG. 2 shows a back perspective view of the multi-turn sensor 100 of FIG. 1. For the purpose of description, the front side of the multi-turn sensor 100 is assumed to be the side on which an input shaft 102 (or simply a shaft) is located, and the back side of the multi-turn sensor 100 is assumed to be the side opposite from the front side. However, it will be understood that one or more features of the present disclosure do not necessarily require such designation of sides. Accordingly, one or more features of the present disclosure can also apply if the input shaft side is called a back side, and the corresponding opposite side is called a front side.

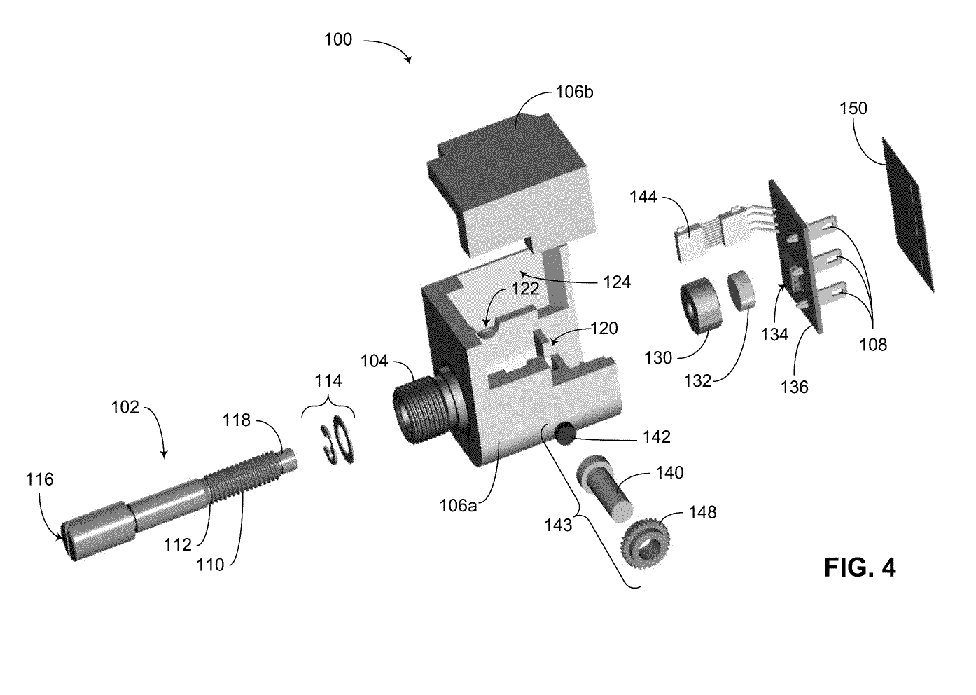

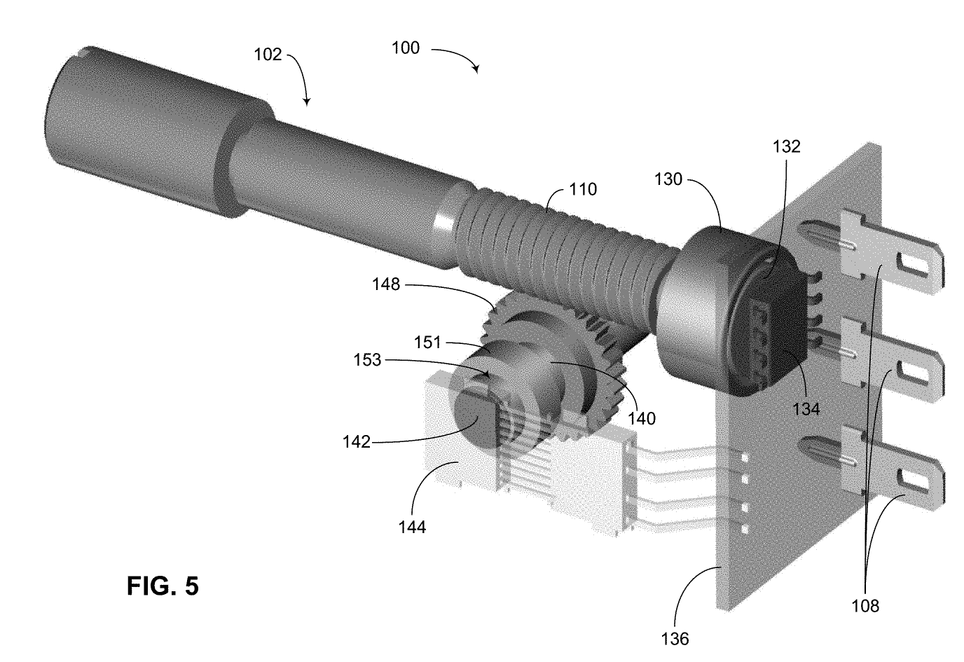

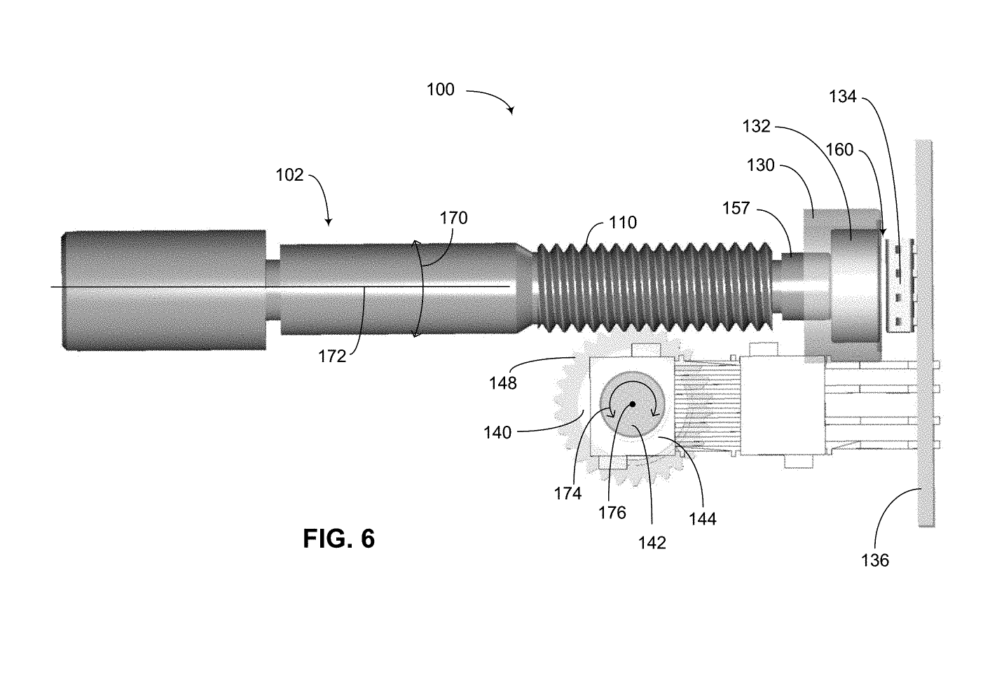

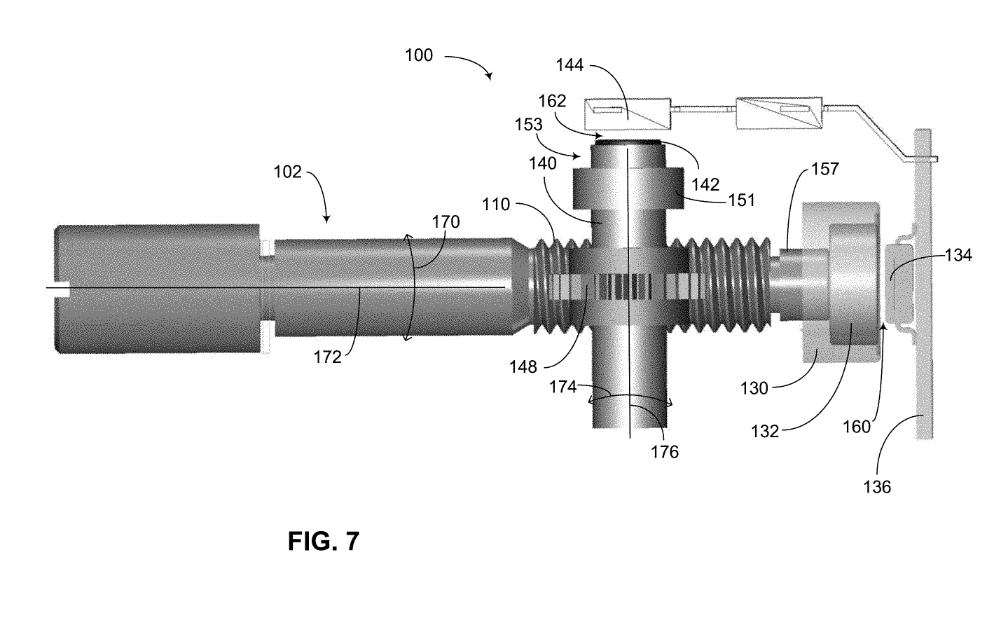

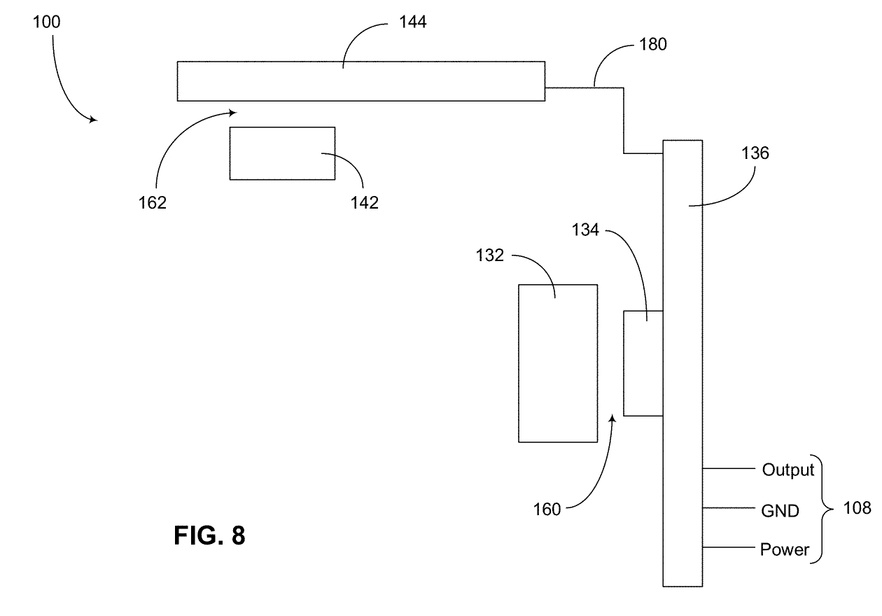

Referring to FIGS. 1-8, FIG. 3 shows an exploded view of the multi-turn sensor 100 of FIG. 1 in a back perspective view. FIG. 4 shows an exploded view of the multi-turn sensor 100 of FIG. 1 in a front perspective view. FIG. 5 shows a back perspective view of the multi-turn sensor 100 of FIG. 1, but with some parts removed to better show internal workings. FIG. 6 shows a side view of the assembly of FIG. 5. FIG. 7 shows a bottom view of the assembly of FIG. 5. FIG. 8 depicts a block diagram of an example of how the multi-turn sensor 100 of FIG. 1 can be read out.

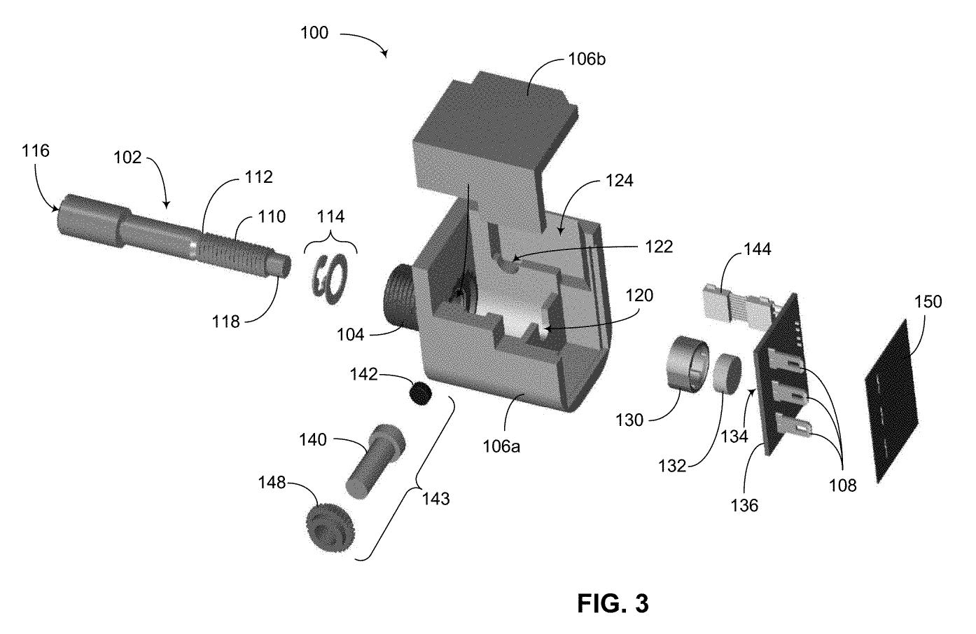

FIGS. 1-4 show that in some embodiments, the multi-turn sensor 100 can include a shaft 102 having a first end (116 in FIGS. 3 and 4) and a second end (118 in FIGS. 3 and 4). The first end 116 can be configured to couple with any part (e.g., another shaft, directly or through some mechanism such as a gear mechanism) for which rotational position information is desired. As described herein, the second end can be configured to hold a first magnet (132 in FIGS. 3 and 4) directly or with a magnet holder (130 in FIGS. 3 and 4).

Referring to FIGS. 1-4, one or more portions of the shaft 102 can be supported by a housing 106 and/or related parts associated with the housing, so as to allow the shaft 102 to rotate about its longitudinal axis. For example, clip(s), washer(s), etc. (collectively indicated as 114 in FIGS. 3 and 4) can be provided to securely retain the shaft 102 (e.g., at a notched portion 112) relative to the housing 106. In another example, an appropriately shaped cutout (120 in FIGS. 3 and 4) can be provided within the housing 106 to provide support for a portion of the shaft 102 near its second end 118. As described herein, the housing 106 can include other cutout(s), recess(es), etc., dimensioned to accommodate other parts of the multi-turn sensor 100.

In the example shown in FIGS. 1-4, the housing 106 can be implemented as a single piece, or include a plurality of pieces. For example, and as shown in FIGS. 3 and 4, the housing 106 of FIGS. 1 and 2 can include first and second pieces 106a, 106b; and such pieces can be configured to provide various functionalities, as well as assembly, of the multi-turn sensor 100.

In the example shown in FIGS. 1-4, the multi-turn sensor 100 is shown to be configured to be mountable to another structure. For example, an externally threaded portion 104 can allow the multi-turn sensor 100 to be hole-mounted to another structure. It will be understood that a multi-turn sensor having one or more features as described herein can also be mounted to another structure in other manners. It will also be understood that a multi-turn sensor having one or more features as described herein may or may not include such mounting features.

In the example shown in FIGS. 1-4, the multi-turn sensor 100 is shown to include three example input/output (I/O) terminals 108. It will be understood that a multi-turn sensor having one or more features as described herein can include other numbers of I/O terminals, including the example described herein in reference to FIGS. 9-11.

In the example shown in FIGS. 1-4, the multi-turn sensor 100 is shown to include a shielding component (e.g., 150 in FIGS. 2-4) such a shielding plate, sheet, layer, etc. Such a shielding component can be configured and positioned to, for example, provide shielding functionality for electronic circuits within the multi-turn sensor 100 from radiation such as x-ray and/or other forms of electromagnetic signals or noises. It will be understood that an additional shielding component can also be implemented at another location of the multi-turn sensor 100. It will also be understood that a multi-turn sensor having one or more features as described herein may or may not include such shielding component(s).

Referring to the exploded views of FIGS. 3 and 4, as well as the views of FIGS. 5-7 (in which the housing and other portions are removed from view), it is noted that in some embodiments, a first magnet 132 can be mounted to the second end (118 in FIGS. 3 and 4) of the shaft 102. For example, a magnet holder 130 can be configured to be secured to the second end 118 of the shaft 102, and to receive and secure the first magnet 132, such that the first magnet 132 is able to rotate with the shaft 102. In some embodiments, the first magnet 132 can be a cylindrical shaped magnet having a longitudinal axis, and such a longitudinal axis of the first magnet 132 can have an approximately co-axial arrangement with the longitudinal axis (172 in FIGS. 6 and 7) of the shaft 102. Examples related to the first magnet 132 and related magnetic sensor are described herein.

In some embodiments, a first magnetic sensor 134 can be implemented relative to the first magnet 132 so as to allow measurement of angular position of the first magnet 132, and therefore angular position of the shaft 102. In some embodiments, the first magnet 132 and the corresponding first magnetic sensor 134 can be implemented in similar manners as described in U.S. Pat. No. 9,593,967 titled HIGH-RESOLUTION NON-CONTACTING MULTI-TURN SENSING SYSTEMS AND METHODS, which is expressly incorporated by reference in its entirely, and its disclosure is to be considered part of the specification of the present application.

For example, the first magnet 132 can be implemented to be in a non-contacting position relative to the first magnetic sensor 134. In some embodiments, the first magnet 132 can be a bipolar and diametrally magnetized magnet so as to yield variable orthogonal and parallel magnetic fluxes to the first magnetic sensor 134. In some embodiments, such a first magnet can be separated from the first magnetic sensor 134 by an appropriate working distance, and the first magnetic sensor 134 can be configured to sense and read the angular position of the first magnet 132 with a desired resolution. Such a resolution can be, for example, at least 10 bit resolution, at least 11 bit resolution, at least 12 bit resolution, at least 13 bit resolution, at least 14 bit resolution, at least 16 bit resolution, or higher than 16 bit resolution. In some embodiments, the first magnetic sensor 134 can include a quadrature Hall-effect sensor assembly having Hall-effect sensors. Such Hall-effect sensors may or may not be formed as integrated sensors. Although the first magnetic sensor 134 is described in the context of Hall-effect sensors, it will be understood that other types of sensors can also be implemented. For example, sine-cosine magneto-resistive (MR) sensors or giant magnetic resistive (GMR) sensors can be utilized (e.g., in a bridge configuration).

Configured in the foregoing example manner, a gap (160 in FIGS. 6 and 7) can be provided between the first magnet 132 and the first magnetic sensor 134, so as to provide angular position sensing functionality in a non-contacting manner. In some embodiments, and as described herein, such an angular position sensing functionality can include sensing of the angular position of the first magnet 132, and thus the angular position of the shaft 102 in this example, within a given turn of the shaft 102.

FIGS. 3-7 also show that in some embodiments, a second magnet 142 and a corresponding second magnetic sensor 144 can be provided and configured to, for example, sense a turn number of the shaft 102. In the example shown in FIGS. 3-7, the second magnet 142 can be mounted to a sensor end of a second shaft 140. Although such a second magnet 142 is shown to be mounted directly onto an appropriately dimensioned sensor end of the second shaft 140, it will be understood that the second magnet 142 can also be mounted using a magnet holder.

Referring to FIGS. 3-7, one can see that the second shaft 140 can be arranged such that its axis of rotation is approximately perpendicular to the axis of rotation of the shaft 102. Accordingly, for the purpose of description, the axis of rotation of the shaft 102 can be along a longitudinal direction, and the axis of rotation of the second shaft 140 can be along a lateral direction with respect to the shaft 102. In the views depicted in FIGS. 6 and 7, the axis of rotation of the shaft 102 is indicated as 172, and the corresponding rotation of the shaft 102 is indicated as 170. Similarly, the axis of rotation of the second shaft 142 is indicated as 176, and the corresponding rotation of the second shaft 140 is indicated as 174.

While the lateral direction of the second shaft 140 is shown to extend side-to-side in the example of FIGS. 3-7, it will be understood that the second shaft 140 can extend in other lateral directions (e.g., up-and-down). Thus, it will be understood that the second magnet 142 and the corresponding magnetic sensor 144 can be located at other lateral positions of the housing 106 (than the example side position as shown).

Referring to FIGS. 3-7, in some embodiments, a gear mechanism such as a gear wheel 148 can be provided and coupled with the second shaft 140, so as to allow simultaneous rotation about the axis of rotation 176 of the second shaft 140. Such a gear wheel can be configured to mate with a threaded portion 110 of the shaft 102, as shown in FIGS. 5-7. Parameters such as pitch of the threaded portion 110 of the shaft 102, and diameter of the gear wheel 148 (having the mating teeth) associated with the second shaft 140, can be selected to provide a desired gear ratio between the shaft 102 and the second shaft 140. For example, such a gear ratio can be selected to provide one turn of the second shaft 140 (and thus the second magnet 142) for one turn of the shaft 102. It will be understood that other gear ratio values can also be implemented.

In the example of FIGS. 3-7, the second shaft 140 and the gear wheel 148 are depicted as separate pieces that fit together. It will be understood that in some embodiments, an assembly that includes the second shaft 140 the gear wheel 148 can be implemented as a single piece part, or a plurality of parts assembled together.

In the example of FIGS. 3-7, and referring more particularly to FIGS. 4, 5 and 7, the second shaft 140 can include an increased-diameter portion 151 provided near the magnet end, so as to provide an end portion 153 dimensioned to allow securing of the end portion 153, in a rotatable manner, by the cutout (122 in FIG. 4) defined by the housing (106b in FIG. 4). The other end of the second shaft 140 can also be secured by a corresponding cutout in the housing in a rotatable manner.

Configured in the foregoing manner, the second magnet 142 can be positioned close to the second magnetic sensor 144 with a gap (162 in FIG. 7), so as to provide non-contacting sensing functionality with the magnet (142)/sensor (144) arrangement, similar to that of the magnet (132)/sensor (134) arrangement. Thus, in some embodiments, the second magnet 142 and the corresponding second magnetic sensor 144 can be implemented in similar manners as described herein in reference to the first magnet 132 and the first magnetic sensor 134.

In the example of FIGS. 3-7, and referring more particularly to FIGS. 3, 6 and 7, the shaft 102 can include an end portion 157 that is not covered by the magnet holder 130. Such a portion can be dimensioned to be received and supported by the above-described cutout 120 defined by the housing (106a in FIG. 3). Such an engagement of the shaft 102 and the cutout 120 can allow the shaft 102 to rotate in a secure manner while maintaining the non-contact arrangement of the magnet 132 and the corresponding magnetic sensor 134.

Referring to FIGS. 5-7, it is noted that in the example multi-turn sensor 100, rotational movement of the shaft 102 and the corresponding rotational movement of the second shaft 140 are not necessarily limited by any laterally moving parts (relative to respective rotational axes). For example, as the shaft 102 rotates clockwise (CW) when looking at the input end (116 in FIGS. 3 and 4), the second shaft 140 can rotate in a first rotational direction (about its rotational axis); and such respective rotations can continue beyond one turn, and without physical stop features associated with laterally moving parts. In reverse, as the shaft 102 rotates counter-clockwise (CCW), the second shaft can rotate in a second rotational direction opposite the first rotational direction, and again without the physical stop features. Thus, the multi-turn sensor 100 can allow rotational position sensing of the shaft 102 for a fraction of a turn, one or more turns, or any combination thereof.

In some embodiments, the multi-turn sensor 100 can allow rotational position sensing of the shaft 102 for multiple turns. As described above, such multiple turns can be achieved without necessarily having physical stop features. If the first magnet 132 and the corresponding magnetic sensor 134 are configured to provide an N-bit resolution (e.g., N=16), then such an angular resolution can be maintained for every turn of a desired number of turns of the shaft 102, since the turn number can be obtained independently by the second magnet 142 and the corresponding second magnetic sensor 144. In other words, any rotational position of the shaft 102 can be determined within the desired number of turns, with the same resolution as the resolution of the first magnet (132)/sensor (134) assembly.

In some embodiments, the second magnet (142)/sensor (144) assembly can be configured to provide a resolution same as or different than that of the first magnet (132)/sensor (134) assembly. In applications where the second magnet (142)/sensor (144) assembly is utilized for turn counting, its resolution can be lower than that of the first magnet (132)/sensor (134) assembly.

In some embodiments, the multi-turn sensor 100 as described herein can provide excellent performance features. For example, linearity of the sensor 100 can have an error of 0.05% or less, and backlash error can be less than 1 degree.

In some embodiments, the multi-turn sensor 100 as described herein can be configured to operate with different operating parameters. For example, input power supply can be based on 5V or 10V, and its current consumption can be about 10 mA. The shaft 102 and the related mechanical parts can be configured to have a start torque of about 1 oz-in, and a running torque of about the same amount. Such a shaft and related mechanical parts can be configured to provide, for example, at least 20 million shaft rotations. As described herein, some or all of the electronics associated with the multi-turn sensor 100 can be protected with a shielding component.

In some embodiments, a multi-turn sensor having one or more features as described herein can be configured to obtain sensed analog signals from each of the first sensor (134) and the second sensor (144) and provide a combined output signal, separate output signals, or some combination thereof. Such output signal(s) can have an analog format, a digital format, or some combination thereof.

For example, an output signal can be based on the sensed analog signals from the sensor(s), without processing. In another example, an output signal can be a digital signal generated by processing of the sensed analog signal (e.g., including analog-to-digital conversion (ADC)).

In yet example, a sensed analog signal from one sensor can be processed and digitized relatively close to a respective sensor element (e.g., on the same sensor device), so as to minimize or reduce degradation of the analog signal. Such a digital signal can be further processed (e.g., combined with a digital signal from another sensor), and the resulting processed digital signal can be converted to an analog format (e.g., with a digital-to-analog converter (DAC)) as an output. Such an analog output signal with reduced degradation (e.g., resulting over time with use of one or more parts of the multi-turn sensor) can be advantageous, especially when an analog output is required or desired.

FIG. 8 shows a block diagram of a readout configuration that can be implemented for the example multi-turn sensor 100 of FIGS. 1-7. For the purpose of description, it is assumed that each of the sensors 134, 144 generates respective digital signals from the respective sensed analog signals. In FIG. 8, the digital signal from the second sensor 144 can be routed (e.g., indicated as 180) to a signal processing circuit in a circuit board 136 (in FIGS. 1-8) so as to be combined with the digital signal from the first sensor 134. The circuit board 136 can include, for example, a DAC to convert the combined digital signal into a combined analog signal; and such a combined analog signal can be output from the multi-turn sensor 100. In FIG. 8, such an analog output signal can be provided to the Output terminal of the I/O terminals 108 of the multi-turn sensor 100. It is noted that in the example of FIG. 8, the I/O terminals 108 can also include a power terminal and a ground terminal for operation of the multi-turn sensor 100.

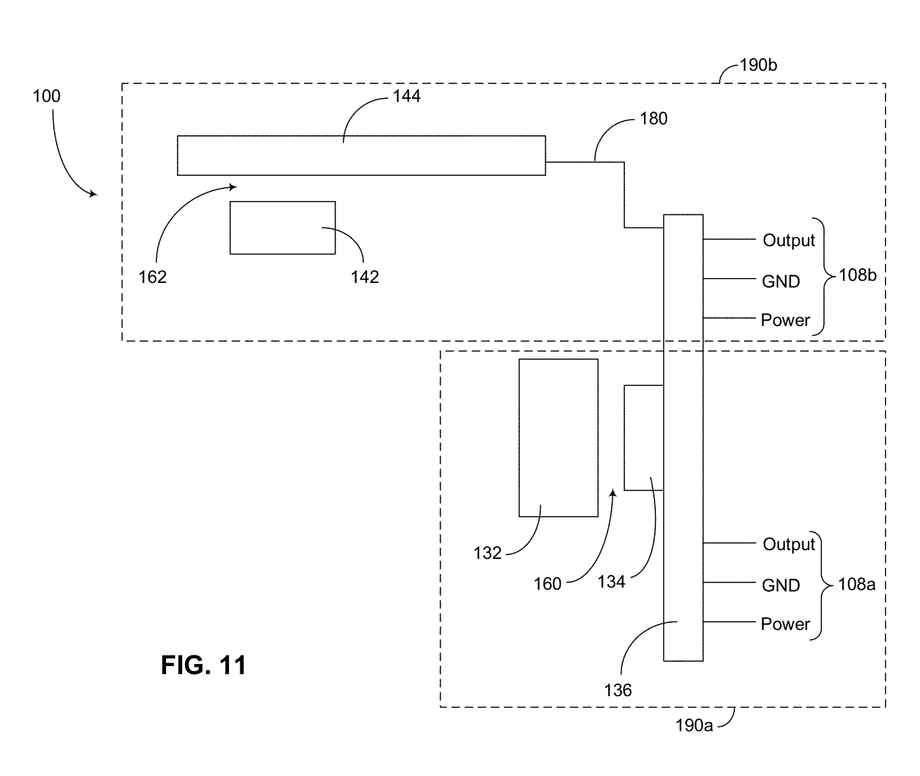

FIGS. 9-11 show an example multi-turn sensor 100 having separate I/O terminals for the first and second sensors (134, 144). In such a configuration, the resulting output can have an analog format, digital format, etc. Accordingly, and as depicted in FIG. 11, the first sensor 134 can have associated with it a set of I/O terminals (indicated as 108a, and including the output). Similarly, the second sensor 144 can have associated with it a set of I/O terminals (indicated as 108b, and including the output).

Accordingly, in FIG. 11, a first assembly including the sensor 134 and the corresponding terminals 108a is indicated as 190a. Similarly, a second assembly including the sensor 144 and the corresponding terminals 108b is indicated as 190b.

In the example of FIGS. 9-11, other portions of the multi-sensor 100, including the first and second magnet/sensor assemblies, can be similar to the multi-sensor 100 of FIGS. 1-8.

The present disclosure describes various features, no single one of which is solely responsible for the benefits described herein. It will be understood that various features described herein may be combined, modified, or omitted, as would be apparent to one of ordinary skill. Other combinations and sub-combinations than those specifically described herein will be apparent to one of ordinary skill, and are intended to form a part of this disclosure. Various methods are described herein in connection with various flowchart steps and/or phases. It will be understood that in many cases, certain steps and/or phases may be combined together such that multiple steps and/or phases shown in the flowcharts can be performed as a single step and/or phase. Also, certain steps and/or phases can be broken into additional sub-components to be performed separately. In some instances, the order of the steps and/or phases can be rearranged and certain steps and/or phases may be omitted entirely. Also, the methods described herein are to be understood to be open-ended, such that additional steps and/or phases to those shown and described herein can also be performed.

Some aspects of the systems and methods described herein can advantageously be implemented using, for example, computer software, hardware, firmware, or any combination of computer software, hardware, and firmware. Computer software can comprise computer executable code stored in a computer readable medium (e.g., non-transitory computer readable medium) that, when executed, performs the functions described herein. In some embodiments, computer-executable code is executed by one or more general purpose computer processors. A skilled artisan will appreciate, in light of this disclosure, that any feature or function that can be implemented using software to be executed on a general purpose computer can also be implemented using a different combination of hardware, software, or firmware. For example, such a module can be implemented completely in hardware using a combination of integrated circuits. Alternatively or additionally, such a feature or function can be implemented completely or partially using specialized computers designed to perform the particular functions described herein rather than by general purpose computers.

Multiple distributed computing devices can be substituted for any one computing device described herein. In such distributed embodiments, the functions of the one computing device are distributed (e.g., over a network) such that some functions are performed on each of the distributed computing devices.

Some embodiments may be described with reference to equations, algorithms, and/or flowchart illustrations. These methods may be implemented using computer program instructions executable on one or more computers. These methods may also be implemented as computer program products either separately, or as a component of an apparatus or system. In this regard, each equation, algorithm, block, or step of a flowchart, and combinations thereof, may be implemented by hardware, firmware, and/or software including one or more computer program instructions embodied in computer-readable program code logic. As will be appreciated, any such computer program instructions may be loaded onto one or more computers, including without limitation a general purpose computer or special purpose computer, or other programmable processing apparatus to produce a machine, such that the computer program instructions which execute on the computer(s) or other programmable processing device(s) implement the functions specified in the equations, algorithms, and/or flowcharts. It will also be understood that each equation, algorithm, and/or block in flowchart illustrations, and combinations thereof, may be implemented by special purpose hardware-based computer systems which perform the specified functions or steps, or combinations of special purpose hardware and computer-readable program code logic means.

Furthermore, computer program instructions, such as embodied in computer-readable program code logic, may also be stored in a computer readable memory (e.g., a non-transitory computer readable medium) that can direct one or more computers or other programmable processing devices to function in a particular manner, such that the instructions stored in the computer-readable memory implement the function(s) specified in the block(s) of the flowchart(s). The computer program instructions may also be loaded onto one or more computers or other programmable computing devices to cause a series of operational steps to be performed on the one or more computers or other programmable computing devices to produce a computer-implemented process such that the instructions which execute on the computer or other programmable processing apparatus provide steps for implementing the functions specified in the equation(s), algorithm(s), and/or block(s) of the flowchart(s).

Some or all of the methods and tasks described herein may be performed and fully automated by a computer system. The computer system may, in some cases, include multiple distinct computers or computing devices (e.g., physical servers, workstations, storage arrays, etc.) that communicate and interoperate over a network to perform the described functions. Each such computing device typically includes a processor (or multiple processors) that executes program instructions or modules stored in a memory or other non-transitory computer-readable storage medium or device. The various functions disclosed herein may be embodied in such program instructions, although some or all of the disclosed functions may alternatively be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid state memory chips and/or magnetic disks, into a different state.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list. The word “exemplary” is used exclusively herein to mean “serving as an example, instance, or illustration.” Any implementation described herein as “exemplary” is not necessarily to be construed as preferred or advantageous over other implementations.

The disclosure is not intended to be limited to the implementations shown herein. Various modifications to the implementations described in this disclosure may be readily apparent to those skilled in the art, and the generic principles defined herein may be applied to other implementations without departing from the spirit or scope of this disclosure. The teachings of the invention provided herein can be applied to other methods and systems, and are not limited to the methods and systems described above, and elements and acts of the various embodiments described above can be combined to provide further embodiments. Accordingly, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A multi-turn sensing device comprising:
a first shaft having a first rotational axis, and a second shaft having a second rotational axis that is approximately perpendicular to the first rotational axis;
a first magnet provided at an end of the first shaft, and a second magnet provided at an end of the second shaft;
a first magnetic sensor provided adjacent the first magnet along the first rotational axis to allow non-contacting sensing of angular position of the first shaft as the first shaft rotates about the first rotational axis, and a second magnetic sensor provided adjacent the second magnet along the second rotational axis to allow non-contacting sensing of angular position of the second shaft as the second shaft rotates about the second rotational axis; and
a gear mechanism configured to couple the first shaft and the second shaft, such that the rotation of the first shaft results in the rotation of the second shaft.

2. The multi-turn sensing device of claim 1, wherein the gear mechanism is configured such that one turn of the first shaft results in one turn of the second shaft.

3. The multi-turn sensing device of claim 2, wherein the one turn of the first shaft results in one turn of the first magnet relative to the first magnetic sensor, and the one turn of the second shaft results in one turn of the second magnet relative to the second magnetic sensor.

4. The multi-turn sensing device of claim 1, wherein the gear mechanism is configured such that one turn of the first shaft results in less than one turn of the second shaft.

5. The multi-turn sensing device of claim 1, wherein the gear mechanism is configured such that one turn of the first shaft results in more than one turn of the second shaft.

6. The multi-turn sensing device of claim 1, wherein each of the first magnet and the second magnet includes a bipolar and diametrally magnetized magnet configured to provide variable orthogonal and parallel magnetic fluxes to the respective magnetic sensor.

7. The multi-turn sensing device of claim 6, wherein each of the first magnetic sensor and the second magnetic sensor is configured to operate in quadrature mode, and includes a plurality of Hall-effect sensors, a plurality of magneto-resistive (MR) sensors, or a plurality of giant magnetic resistive (GMR) sensors.

8. The multi-turn sensing device of claim 6, wherein each of the first magnetic sensor and the second magnetic sensor includes four sensors positioned in quadrature and configured to operate as sine-cosine sensors.

9. The multi-turn sensing device of claim 1, further comprising an interface configured to process output signals from each of the first magnetic sensor and the second magnetic sensor and provide one or more output signals.

10. The multi-turn sensing device of claim 9, wherein each magnetic sensor or the interface is configured to generate a digital signal representative of the angular position of the respective magnet, the interface configured to convert the digital signal into a corresponding analog signal as the output signal.

11. The multi-turn sensing device of claim 9, wherein the interface is configured to generate a common output signal representative of a combination of the output signals of the first and second magnetic sensors.

12. The multi-turn sensing device of claim 11, wherein the output signal of the first magnetic sensor is representative of the angular position of the first shaft in a current turn, and the output signal of the second magnetic sensor is representative of a turn number of the first shaft, such that the common output signal includes information about the turn number of the first shaft and the angular position of the first shaft in the current turn.

13. The multi-turn sensing device of claim 9, wherein the interface is configured to generate a device output signal representative of each of the output signals of the first and second magnetic sensors.

14. The multi-turn sensing device of claim 9, wherein at least the first magnetic sensor and the interface are parts of, or disposed on, an application specific integrated circuit (ASIC).

15. The multi-turn sensing device of claim 14, further comprising a shielding layer configured to shield some or all of the ASIC from radiation.

16. The multi-turn sensing device of claim 1, further comprising a housing configured to house the first and second magnetic sensors, the first and second magnets, the second shaft, and at least a portion of the first shaft.

17. The multi-turn sensing device of claim 1, wherein the first shaft is configured to be coupled to an external part, such that the device is able to measure an angular position of the external part in a current turn with the first magnetic sensor, and a turn number of the external part with the second magnetic sensor, such that the device is able to provide information about the turn number of the external part and the angular position of the external part in the current turn.

18. The multi-turn sensing device of claim 1, wherein the gear mechanism includes a threaded portion of the first shaft and a gear wheel configured to engage the threaded portion and turn with the second shaft.

19. A method for sensing rotational position, the method comprising:
sensing an angular position of a first shaft within a given turn of the first shaft about a first rotational axis, the sensing of the angular position including sensing of an angular position of a first magnet provided at an end of the first shaft with a first magnetic sensor provided adjacent the first magnet along the first rotational axis to allow non-contacting sensing of the angular position of the first shaft; and
determining a turn number of the first shaft with a second shaft that is coupled to the first shaft through a gear mechanism having a second rotational axis that is approximately perpendicular to the first rotational axis, the determining of the turn number including sensing of an angular position of a second magnet provided at an end of the second shaft with a second magnetic sensor provided adjacent the second magnet along the second rotational axis to allow non-contacting sensing of the angular position of the second shaft as the second shaft rotates due to the rotation of the first shaft.

20. A system comprising:
a first device for which determination of its position is desired; and
a multi-turn sensor coupled to the first device and configured to provide an output signal representative of the position of the first device, the multi-turn sensor including a first shaft having a first rotational axis and configured to provide the coupling with the first device, and a second shaft having a second rotational axis that is approximately perpendicular to the first rotational axis, the multi-turn sensor further including a first magnet provided at an end of the first shaft, and a second magnet provided at an end of the second shaft, the multi-turn sensor further including a first magnetic sensor provided adjacent the first magnet along the first rotational axis to allow non-contacting sensing of angular position of the first shaft as the first shaft rotates about the first rotational axis, and a second magnetic sensor provided adjacent the second magnet along the second rotational axis to allow non-contacting sensing of angular position of the second shaft as the second shaft rotates about the second rotational axis, the multi-turn sensor further including a gear mechanism configured to couple the first shaft and the second shaft, such that the rotation of the first shaft results in the rotation of the second shaft.
